(19) United States
(12) Patent Application Publication
(10) Pub. No.: US 2007/0235787 A1
(43) Pub. Date: Oct. 11, 2007

(54) Capacitor device having three-dimensional structure

(75) Inventors: Yoshihisa Nagano, Osaka (JP); Yuji Judai, Kyoto (JP)

Correspondence Address: MCDERMOTT WILL & EMERY LLP, 600 13TH STREET, N.W., WASHINGTON, DC, 20005-3096, US

(73) Assignee: Matsushita Electric Industrial Co., Ltd.

(21) Appl. No.: 11/407,048

(22) Filed: Apr. 20, 2006

(30) Foreign Application Priority Data
Jun. 3, 2005 (JP) 2005-163965

(51) Int. Cl. H01L 27/108

(52) U.S. Cl. 257/301; 257/E27.084

(57) ABSTRACT

A capacitor device having a three-dimensional structure includes: a lower electrode formed on a semiconductor substrate to have a three-dimensional shape; a capacitor insulating film formed to cover the lower electrode and made of a ferroelectric material; and an upper electrode formed on the capacitor insulating film to have a step portion. A stress control layer is formed on the upper electrode to cause tensile stress and function as a moisture diffusion barrier.

### CROSS-REFERENCE TO RELATED APPLICATIONS

This application claims priority under 35 U.S.C. §119 on Patent Application No. 2005-163965 filed in Japan on Jun. 3, 2005, the entire contents of which are hereby incorporated by reference.

### BACKGROUND OF THE INVENTION

(1) Field of the Invention

The present invention relates to capacitor devices using a ferroelectric material as a capacitor insulating film and having a three-dimensional structure.

(2) Description of Related Art

To commercialize a RAM which enables high-speed writing and reading at an unprecedentedly low voltage, vigorous research and development has been made on capacitor devices made of a ferroelectric material having a characteristic of spontaneous polarization. To implement a megabit-class semiconductor memory device to be mounted on an LSI composed of a complementary metal oxide semiconductor (CMOS) with design rules of 0.18 μm or below, in particular, a capacitor device having a three-dimensional structure capable of providing a large capacitance with a small area should be developed.

To prevent malfunctions of the above-mentioned capacitor devices having a three-dimensional structure and thus achieve high-reliability semiconductor memory devices, it is most important to increase the polarization of a ferroelectric capacitor device and thus facilitate discriminating between data “0” and data “1”.

Simple and effective methods for increasing the polarization include a method in which a stress is externally applied to ferroelectric capacitor devices. It is assumed, based on the present inventors' experimental results and known art references (see, for example, Japanese Unexamined Patent Publication No. 2002-33460), that while application of a tensile stress to a capacitor device increases the polarization, application of a compressive stress thereto decreases the polarization.

In view of the above, the polarization can be increased by achieving the structure of a ferroelectric capacitor device in which a tensile stress is externally applied to the ferroelectric capacitor device having a three-dimensional structure.

Disclosed in, for example, Japanese Unexamined Patent Publication No. 2004-39699 (Paragraphs [0047] and [0048] at Page 7, FIG. 3, Paragraphs [0063] through [0107] at Pages 8 through 13, and FIGS. 7 through 18) is a method in which a capacitor-protecting insulating film causing tensile stress is formed on a capacitor device to reduce the compressive stress applied thereto.

A silicon oxide film causing tensile stress typically has a high moisture content. Therefore, in a case where a silicon oxide film causing tensile stress is formed as an interlayer insulating film over a ferroelectric film forming part of a capacitor device, moisture contained in the interlayer insulating film deteriorates the capacitor device. In view of the above, in a known capacitor device, a film causing compressive stress and having a low moisture content is used as an interlayer insulating film formed on a capacitor-protecting insulating film causing tensile stress.

In particular, in comparison with a capacitor device having a plane structure, in a capacitor device having a three-dimensional structure which requires a large polarization, the polarization cannot be expected to significantly increase under the use of a film causing compressive stress as an interlayer insulating film. The reason for this is as follows.

### SUMMARY OF THE INVENTION

The height of a capacitor device having a three-dimensional structure becomes much greater than that of a capacitor device having a plane structure. This makes it necessary to increase the thickness of an interlayer insulating film covering the capacitor device having a three-dimensional structure. With the increasing thickness of the interlayer insulating film, the stress applied from the interlayer insulating film to the capacitor device becomes stronger. Therefore, even if the capacitor device having a three-dimensional structure is formed with a protective insulating film or any other film causing tensile stress, a large compressive stress will be applied to the capacitor device. As a result, the polarization of the capacitor device cannot be expected to increase, and thus the possibility of causing semiconductor memory devices having capacitor devices to malfunction is increased. In other words, when a film causing compressive stress is used as an interlayer insulating film, the reliability of capacitor devices having a three-dimensional structure and using a ferroelectric material for a capacitor insulating film cannot be enhanced.

The present invention has been made to solve the aforementioned conventional problems, and an object of the present invention is to provide a high-reliability capacitor device having a three-dimensional structure while increasing the polarization of the capacitor device by applying a tensile stress to a ferroelectric film and preventing deterioration in the capacitor device due to moisture.

In order to achieve the above object, a capacitor device of the present invention comprises a stress control layer formed on an upper electrode and functioning as a moisture diffusion barrier.

More specifically, a capacitor device of the present invention having a three-dimensional structure includes: a lower electrode formed over a semiconductor substrate to have a three-dimensional shape; a capacitor insulating film formed to cover the lower electrode and made of a ferroelectric material; an upper electrode formed on the capacitor insulating film to have a step portion; and a stress control layer causing tensile stress and functioning as a moisture diffusion barrier, the stress control layer being formed over the upper electrode.

According to the capacitor device of the present invention, an insulating film having a high moisture content and causing tensile stress can be formed on the stress control layer. This permits effective application of a tensile stress to the ferroelectric film and can prevent deterioration in the capacitor device due to moisture. As a result, a high-reliability capacitor device having a three-dimensional structure can be achieved.

In the capacitor device of the present invention, the stress control layer preferably functions as a hydrogen diffusion barrier. This structure can prevent the capacitor device from being deteriorated due to entry of hydrogen into the ferroelectric film.

In the capacitor device of the present invention, the stress control layer is preferably a single layer made of any one of titanium nitride, titanium aluminum nitride, titanium aluminum oxide, tantalum aluminum nitride, tantalum aluminum oxide, and tantalum silicon nitride or a multilayer made of at least two thereof. With this structure, a stress control layer causing tensile stress and functioning as a moisture diffusion barrier can be formed with reliability.

In the capacitor device of the present invention, the stress control layer is preferably formed to cover the step portion of the upper electrode. With this structure, a tensile stress can be certainly applied to the ferroelectric film formed below the upper electrode and having a three-dimensional shape.

It is preferable that the capacitor device of the present invention further includes a first interlayer insulating film formed on the stress control layer and causing tensile stress. With this structure, a tensile stress can be certainly applied to the ferroelectric film. In this case, the first interlayer insulating film is preferably a silicon oxide film formed by thermal chemical vapor deposition using ozone and tetraethoxysilane as its materials.

It is preferable that the capacitor device of the present invention further includes a second interlayer insulating film formed between the upper electrode and the stress control layer and causing tensile stress. With this structure, the vertical dimension of the upper electrode can be reduced, and a stress control layer can be formed with reliability. In this case, the second interlayer insulating film is preferably a silicon oxide film formed by thermal chemical vapor deposition using ozone and tetraethoxysilane as its materials and subjected to heat treatment.

It is preferable that the capacitor device of the present invention further includes a third interlayer insulating film formed over the semiconductor substrate and having an opening and the lower electrode is formed on the inner wall and bottom of the opening to form a concave shape in cross section. Furthermore, the capacitor device of the present invention may further include a fourth interlayer insulating film formed on part of the semiconductor substrate, wherein the lower electrode may be formed on the fourth interlayer insulating film to have a convex shape in cross section.

It is preferable that the capacitor device of the present invention further includes a transistor formed on the semiconductor substrate and including a source and a drain, wherein the lower electrode is electrically connected through a contact plug to the source or drain.

In the capacitor device of the present invention, the capacitor insulating film is preferably made of any one of SrBi₂(TaₓNb₁₋ₓ)₂O₉ (0≦x≦1), Pb(ZrₓTi₁₋ₓ)O₃ (0≦x≦1), (BiₓLa₁₋ₓ)₄Ti₃O₁₂ (0≦x≦1), and (BaₓSrₓ₋₁)TiO₃ (0≦x≦1).

### BRIEF DESCRIPTION OF THE DRAWINGS

FIG. 1 is a cross-sectional view illustrating a capacitor device according to a first embodiment of the present invention.

FIG. 2 is a graph illustrating the polarization characteristics of the capacitor device according to the first embodiment.

FIG. 3 is a cross-sectional view illustrating another capacitor device according to the first embodiment.

FIG. 4 is a cross-sectional view illustrating still another capacitor device according to the first embodiment.

FIG. 5 is a cross-sectional view illustrating yet another capacitor device according to the first embodiment.

FIG. 6 is a cross-sectional view illustrating a capacitor device according to a second embodiment.

FIG. 7 is a cross sectional view illustrating another capacitor device according to the second embodiment.

### DETAILED DESCRIPTION OF THE INVENTION

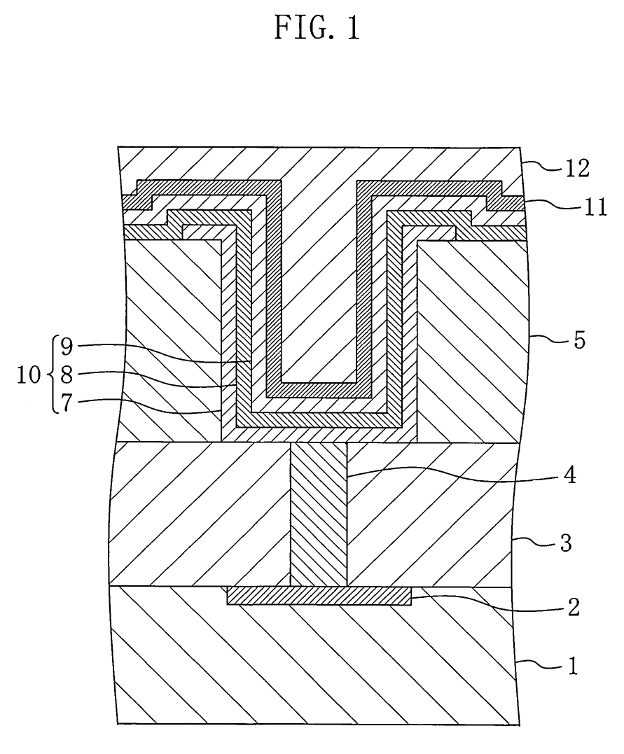

A capacitor device according to a first embodiment of the present invention will be described with reference to the drawings. FIG. 1 illustrates a cross-sectional shape of the capacitor device according to the first embodiment.

As illustrated in FIG. 1, a source or drain region 2 of a transistor is formed in the vicinity of the top surface of a semiconductor substrate 1. A first interlayer insulating film 3 of silicon dioxide (SiO₂), silicon nitride (SiN) or the like is formed on the semiconductor substrate 1. A contact plug 4 of tungsten or low-resistivity polysilicon doped with an n-type impurity is formed to pass through the first interlayer insulating film 3 and be in contact at its lower end with the source or drain region 2.

A second interlayer insulating film 5 of SiO₂ or SiN is formed on the first interlayer insulating film 3 to have an opening formed to expose the top surface of the contact plug 4. In order to increase the capacitance of the capacitor element 10, the second interlayer insulating film 5 is preferably as thick as possible. In this embodiment, the second interlayer insulating film 5 is formed to have a thickness of 1 μm or more. The diameter of the opening is preferably 0.2 μm through 1 μm both inclusive. In this embodiment, it is approximately 0.6 μm.

A lower electrode 7 is formed so as to cover the bottom and inner wall of the opening and be electrically connected to the contact plug 4 and does not only function as an electrode of the capacitor device but also functions as an oxygen barrier for preventing oxygen from reaching the contact plug 4 during high-temperature annealing in an oxygen atmosphere which is necessary for crystallization of a thin ferroelectric film. A precious metal or its oxide, such as platinum (Pt), iridium (Ir), iridium dioxide (IrO₂), ruthenium (Ru), or ruthenium dioxide (RuO₂), is used as a material of the lower electrode 7. The lower electrode 7 preferably has a thickness of 10 nm through 50 nm both inclusive. In this embodiment, a 30-nm-thick IrO₂ film is used for the lower electrode 7.

The entire surface of the lower electrode 7 is covered with a capacitor insulating film 8 made of SrBi₂(TaₓNb₁₋ₓ)₂O₉ (0≦x≦1). The capacitor insulating film 8 is formed using a film formation method with excellent step coverage. For example, metal organic chemical vapor deposition (MOCVD), atomic layer deposition (ALD) or sputtering is preferably used to form the capacitor insulating film 8. Furthermore, the capacitor insulating film 8 is preferably formed at a temperature of approximately 300° C. or more and preferably has a thickness of 12.5 nm through 100 nm both inclusive. In this embodiment the capacitor insulating film 8 has a thickness of 50 nm n.

An upper electrode 9 is formed over the capacitor insulating film 8 to have step portions. A precious metal or its oxide, such as Pt, Ir, IrO₂, Ru, or RuO₂, is preferably used as a material of the upper electrode 9. The upper electrode 9 preferably has a thickness of 10 nm through 50 nm both inclusive. In this embodiment, a 30-nm-thick IrO₂ film is used for the upper electrode 9.

A stress control layer 11 is formed to cover the entire surface of a capacitor element 10 having a three-dimensional structure and composed of the lower electrode 7, the capacitor insulating film 8 and the upper electrode 9. Used as the stress control layer 11 is a single film of any one of titanium nitride (TiN), titanium aluminum nitride (TiAlN), titanium aluminum oxide (TiAlO), tantalum aluminum nitride (TaAlN), tantalum aluminum oxide (TaAlO), and tantalum silicon nitride (TaSiN) or a multilayer film of any two or more thereof.

The use of such a film allows the stress control layer 11 to cause tensile stress. Thus, the stress control layer 11 applies a tensile stress to the capacitor element 10 and functions as a barrier film for preventing moisture or hydrogen from diffusing into the capacitor element 10.

In this embodiment, the stress control layer 11 is preferably adjusted in its thickness or the like to have a tensile stress of 5×10⁹ dyn/cm² or more. In this embodiment, a multilayer film whose upper layer is made of TiN and whose lower layer is made of TiAlN is used as the stress control layer 11, and the TiN layer and the TiAlN layer have thicknesses of 20 nm and 50 nm, respectively. The multilayer film does not only function as the stress control layer but also the TiAlN layer forming the lower layer of the multilayer film and the TiN layer forming the upper layer thereof function as a hydrogen barrier film and an adhesion layer, respectively.

The stress control layer 11 is covered with a third interlayer insulating film 12 of SiO₂, SiN or any other material causing tensile stress. In this manner, a tensile stress can be applied also from the third interlayer insulating film 12 to the capacitor element 10. A SiO₂ film formed by plasma chemical vapor deposition (CVD) typically causes compressive stress. For this reason, in this embodiment, a SiO₂ film formed by thermal CVD using O₃ and tetra ethyl ortho silicate (TEOS) as its materials is used as the third interlayer insulating film 12.

The SiO₂ film formed by thermal CVD has a higher moisture content than the SiO₂ film formed by plasma CVD. Therefore, in a case where the SiO₂ film formed by thermal CVD is used as the third interlayer insulating film 12, the characteristics of the capacitor element 10 may be deteriorated. However, since in this embodiment the stress control layer 11 formed between the capacitor element 10 and the third interlayer insulating film 12 functions as a barrier against moisture, this prevents the characteristics of the capacitor element 10 from being deteriorated even with the use of the SiO₂ film formed by thermal CVD.

The SiO₂ film formed by thermal CVD also contains a smaller amount of hydrogen than the SiO₂ film formed by plasma CVD. However, since the stress control layer 11 functions as a barrier against hydrogen, this prevents the characteristics of the capacitor element 10 from being deteriorated due to hydrogen.

In this embodiment, a boron phosphorous silicate glass (BPSG) film doped with boron (B) and phosphorous (P) is used as the third interlayer insulating film 12 using O₃ and TEOS as its materials. If the conditions on which the third interlayer insulating film 12 is formed are changed, a SiO₂ film causing tensile stress, instead of the BPSG film, can be formed by plasma CVD.

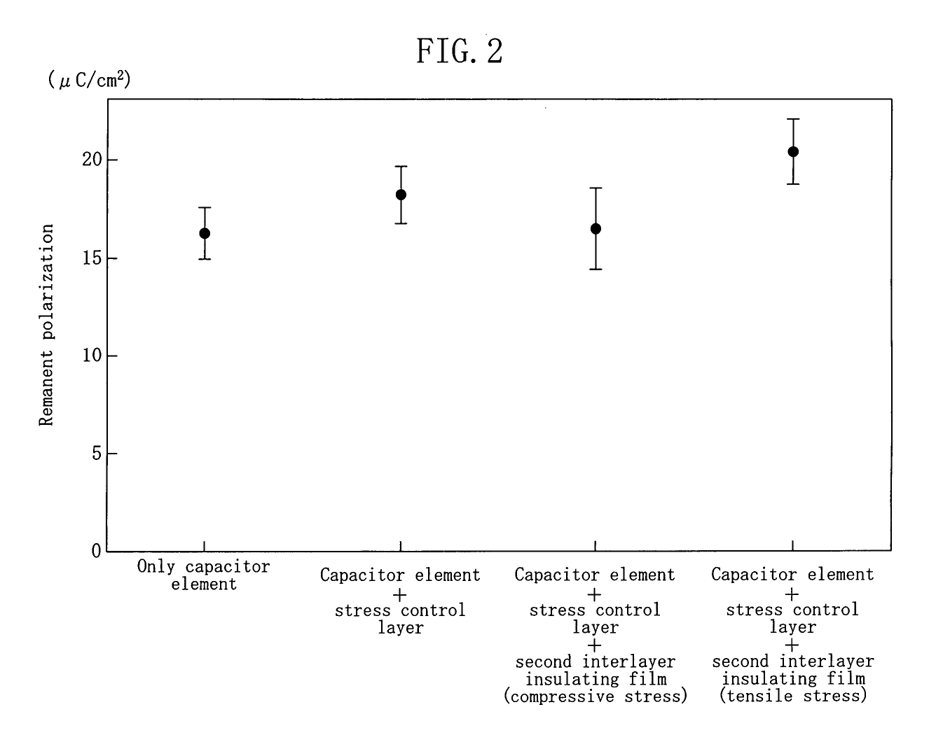

The characteristics of the capacitor element of this embodiment will be described hereinafter with reference to the drawings. FIG. 2 illustrates variations in the remanent polarization (2Pr) of the capacitor element 10 according to a film or films formed on the capacitor element 10 of this embodiment. As illustrated in FIG. 2, when no film is formed on the capacitor element 10, the 2Pr of the capacitor element 10 is approximately 16 μC/cm². When a stress control layer 11 composed of 20-nm-thick TiN and 50-nm-thick TiAlN is formed on the capacitor element 10, the 2Pr increases by approximately 2° C./cm² and thus becomes approximately 18 μC/cm². This shows that a tensile stress can be applied to the capacitor element 10 by the stress control layer 11, resulting in the increased polarization of the capacitor element 10.

In a capacitor element having a three-dimensional structure, a three-dimensional ferroelectric film needs to be formed. It is difficult that the quality of a ferroelectric film in the formation thereof on a flat face becomes equivalent to that of a three-dimensional ferroelectric film in the formation thereof. In particular, part of a ferroelectric film formed on the wall of the opening has a smaller polarization than the film formed on the flat face. Therefore, in a capacitor element having a three-dimensional structure, the 2Pr of the capacitor element is likely to be smaller than that having a plane structure.

However, a larger stress can be applied to part of the ferroelectric film formed on the wall of the opening than to part of the ferroelectric film formed on the flat face in the manner in which a stress control layer 11 is formed to extend along the entire surface of the capacitor element 10 having a three-dimensional structure. Therefore, a tensile stress can be efficiently applied to the capacitor element 10 by the formation of a stress control layer 11 causing tensile stress. As a result, the amount of increase in the 2Pr of the capacitor element 10 having a three-dimensional structure is greater than that of the capacitor element having a plane structure.

When a SiO₂ film causing compressive stress is formed, as the third interlayer insulating film 12, on the stress control layer 11, the 2Pr of the capacitor element 10 becomes approximately 1.5 μC/cm² smaller than when only a stress control layer 11 is formed on the capacitor element 10, i.e., approximately 16.5 μC/cm². The reason for this is that the tensile stress caused by the stress control layer 11 and the compressive stress caused by the third interlayer insulating film 12 cancel each other, thereby reducing the tensile stress applied to the capacitor element 10.

On the other hand, when a SiO₂ film causing tensile stress is formed, as the third interlayer insulating film 12, on the stress control layer 11, the 2Pr of the capacitor element 10 becomes approximately 3.5 μC/cm² larger than when only a stress control layer 11 is formed on the capacitor element 10, i.e., approximately 20 μC/cm², and becomes approximately 4 μC/cm² larger than when no film is formed on the capacitor element 10.

In view of the above, the formation of a stress control layer 11 causing tensile stress on a capacitor element 10 helps increase the polarization of the capacitor element 10.

Furthermore, the formation of a third interlayer insulating film 12 causing tensile stress on the stress control layer 11 can further increase the polarization of the capacitor element 10. In this case, even when a film having a high moisture content is used as a third interlayer insulating film to cause tensile stress, the capacitor element 10 is prevented from being deteriorated due to moisture. The reason for this is that the stress control layer 11 of this embodiment formed under the third interlayer insulating film 12 functions as a barrier against moisture.

Although in this embodiment a ferroelectric material, SrBi₂(TaₓNb₁₋ₓ)₂O₉ (0≦x≦1), is used as a material of the capacitor insulating film 8, Pb(ZrₓTi₁₋ₓ)O₃ (0≦x≦1), (BiₓLa₁₋ₓ)₄Ti₃O₁₂ (0≦x≦1), (BaₓSrₓ₋₁)TiO₃(0≦x≦1), or the like may be used instead.

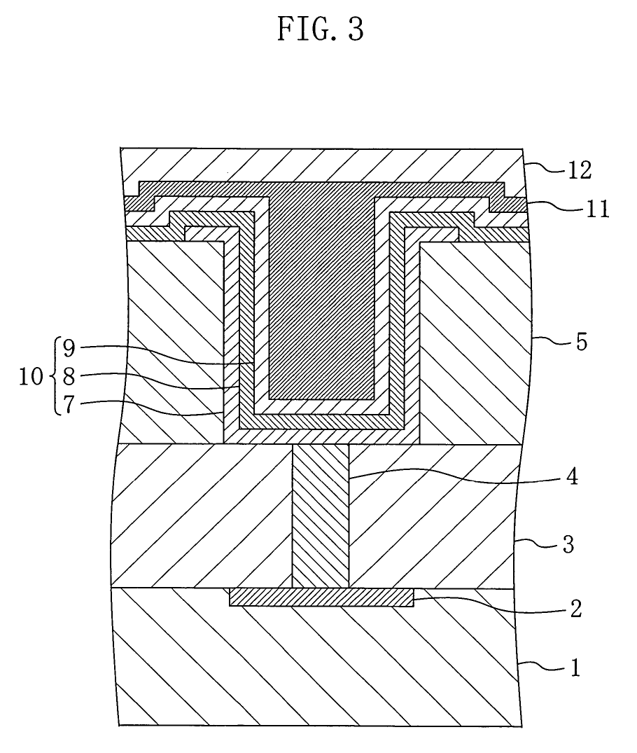

Although the stress control layer 11 is formed as a thin film extending along the entire surface of the capacitor element 10, it may be formed to fill a recess with which the capacitor element 10 is formed as illustrated in FIG. 3. With this structure, the tensile stress applied to the capacitor element 10 can be increased, resulting in the further increased polarization of the capacitor element 10.

When a multilayer film is used as the stress control layer 11, the use of an amorphous-base film as the upper film of the multilayer film can improve the adhesion between the stress control layer 11 and the third interlayer insulating film 12. In a case where the upper film is formed of an insulative material, such as TiAlO, and the lower film is formed of a conductive material, such as TiAlN, the stress control layer 11 can be used as a cell plate line as in a case where the upper film is formed of a conductive material, such as TiN.

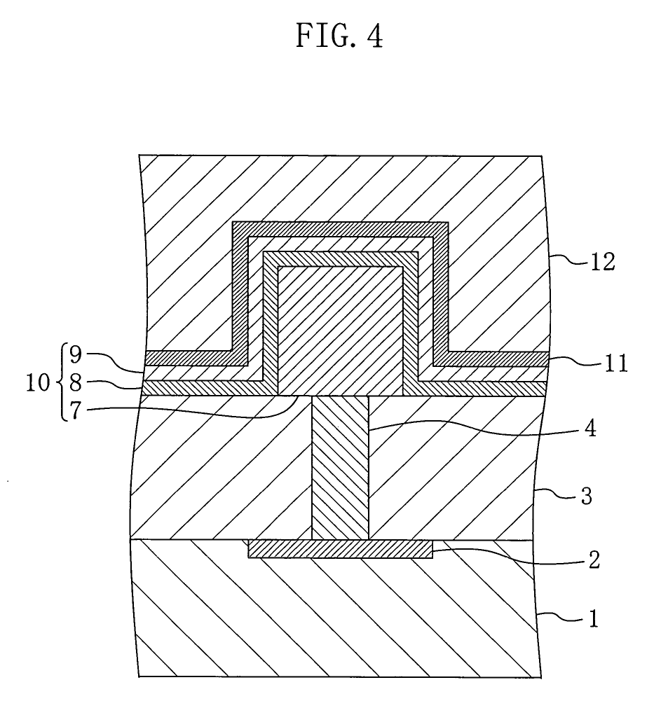

Although in this embodiment a capacitor element forming a concave shape in cross section is described, a capacitor element whose lower electrode forms a convex shape in cross section as illustrated in FIG. 4 provides the same effect.

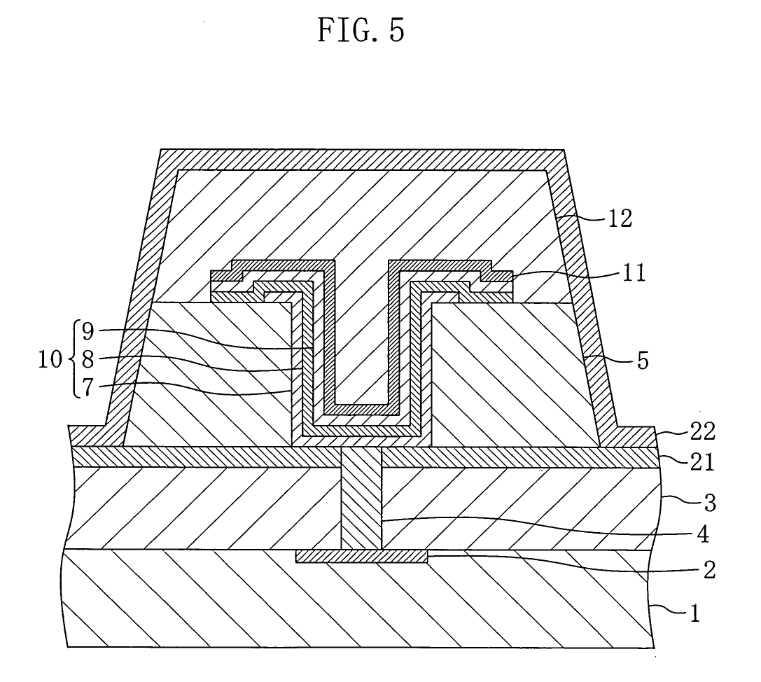

As illustrated in FIG. 5, barrier films 21 and 22 against hydrogen and moisture are further formed to surround the whole capacitor element. This structure can prevent hydrogen and moisture from diffusing from outside into the capacitor element, resulting in the further enhanced reliability of the capacitor element. Alternatively, the barrier films 21 and 22 may cover a combination of a plurality of capacitor elements.

The barrier films 21 and 22 need only be formed of a material having barrier properties against hydrogen and moisture and may be formed of the same material as the stress control layer 11 or a different material from the material of the stress control layer 11.

### Embodiment 2

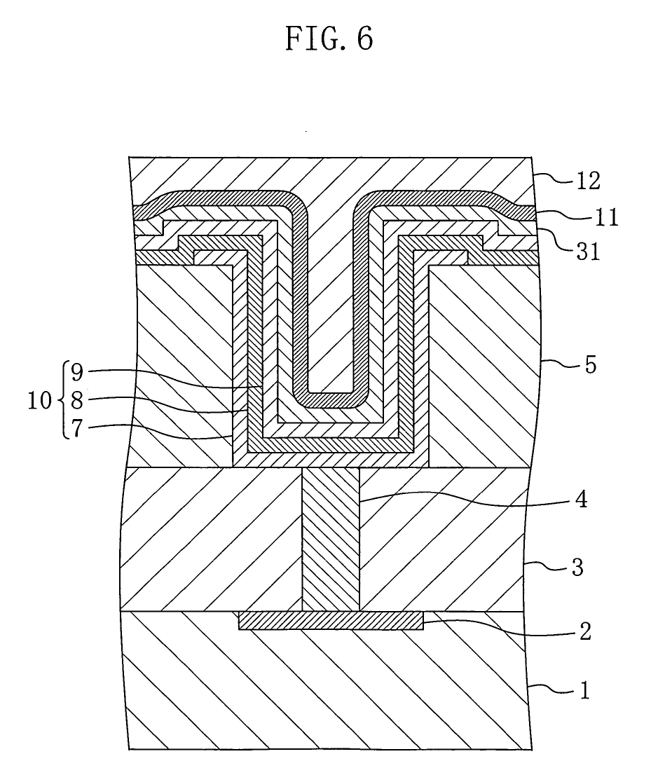

A capacitor device according to a second embodiment of the present invention will be described with reference to the drawings. FIG. 6 illustrates a cross-sectional shape of the capacitor device according to the second embodiment. In FIG. 6, the same components as those in FIG. 1 are identified by the same reference numerals and description will not be given to them.

As illustrated in FIG. 6, a fourth interlayer insulating film 31 causing tensile stress is formed between an upper electrode 9 and a stress control layer 11.

The formation of the fourth interlayer insulating film 31 can improve the step coverage of the stress control layer 11. In general, the stress control layer 11 is formed of metal nitride or metal oxide and therefore formed by sputtering. However, it is difficult to form a film completely covering the corners of the capacitor element in the use of sputtering. The formation of the fourth interlayer insulating film 31 reduces the vertical dimension of a capacitor element 10 having a three-dimensional structure, leading to the rounded corners thereof. This can improve the coverage of the stress control layer 11. Furthermore, since the fourth interlayer insulating film 31 causes tensile stress, this can increase the tensile stress applied to the capacitor element 10.

A SiO₂ film formed by thermal CVD using O₃ and TEOS as its material is used for the fourth interlayer insulating film 31. The SiO₂ film formed by thermal CVD has a high moisture content. However, after the film formation, moisture can be eliminated from the fourth interlayer insulating film 31 by subjecting the fourth interlayer insulating film 31 to heat treatment in an oxygen atmosphere. Simultaneously, hydrogen can also be eliminated from the fourth interlayer insulating film 31 by the above heat treatment.

After the elimination of moisture and hydrogen from the fourth interlayer insulating film 31 by heat treatment, the fourth interlayer insulating film 31 is covered with the stress control layer 11 having barrier properties against moisture and hydrogen. This prevents the characteristics of the capacitor element 10 from being deteriorated due to further absorption of moisture and hydrogen into the fourth interlayer insulating film 31.

In this embodiment, a 50-nm-thick SiO₂ film is formed, as the fourth interlayer insulating film 31, by thermal CVD, and the formed SiO₂ film is subjected to oxygen annealing at 650° C. for one minute.

The formation of a fourth interlayer insulating film 31 allows isolation of an upper electrode 9 from a stress control layer 11. When a plurality of capacitor elements 10 are formed above a semiconductor substrate 1 and a conductive stress control layer 11 made of TiAlN or the like is formed to be in direct contact with the entire surface of each of upper electrodes 9, all the capacitor elements 10 are connected in parallel with one another. However, also when a common stress control layer 11 is formed, the formation of a fourth interlayer insulating film 31 between the stress control layer 11 and upper electrodes 9 facilitates isolating the capacitor elements 10 from one another or combining some of the capacitor elements 10.

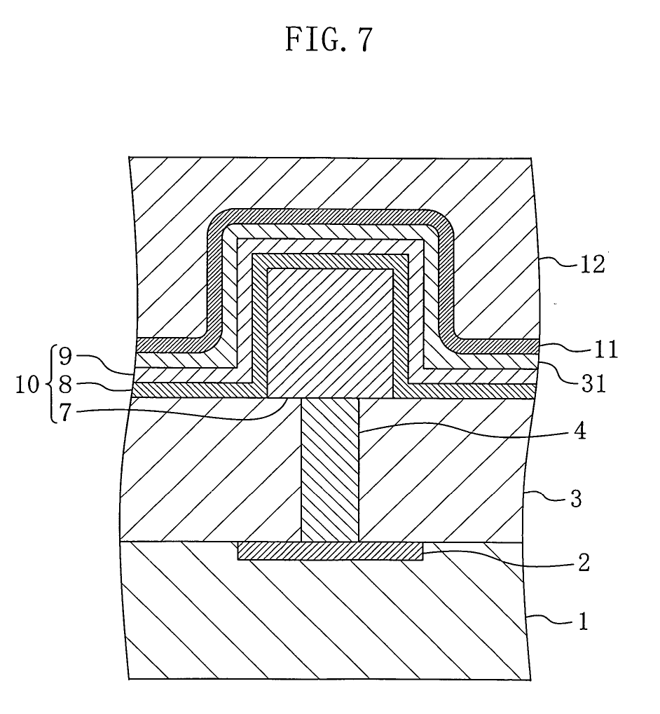

Although in this embodiment a capacitor device including a capacitor element 10 that forms a concave shape in cross section is described, a capacitor device whose lower electrode 7 forms a convex shape in cross section as illustrated in FIG. 7 provides the same effect.

As described above, in a capacitor device of the present invention, application of a tensile stress to a ferroelectric film increases the polarization of the capacitor device and prevents deterioration in the capacitor device due to moisture, resulting in achievement of a high-reliability capacitor device having a three-dimensional structure. The capacitor device of the present invention is useful as a capacitor device using a ferroelectric material for a capacitor insulating film and having a three-dimensional structure.

What is claimed is:

1. A capacitor device having a three-dimensional structure, said capacitor device comprising:
a lower electrode formed over a semiconductor substrate to have a three-dimensional shape;
a capacitor insulating film formed to cover the lower electrode and made of a ferroelectric material;
an upper electrode formed on the capacitor insulating film to have a step portion; and
a stress control layer causing tensile stress and functioning as a moisture diffusion barrier, the stress control layer being formed over the upper electrode.

2. The capacitor device of claim 1, wherein
the stress control layer functions as a hydrogen diffusion barrier.

3. The capacitor device of claim 1, wherein
the stress control layer is a single layer made of any one of titanium nitride, titanium aluminum nitride, titanium aluminum oxide, tantalum aluminum nitride, tantalum aluminum oxide, and tantalum silicon nitride or a multilayer made of at least two thereof.

4. The capacitor device of claim 1, wherein
the stress control layer is formed to cover the step portion of the upper electrode.

5. The capacitor device of claim 1 further comprising
a first interlayer insulating film formed on the stress control layer and causing tensile stress.

6. The capacitor device of claim 5, wherein
the first interlayer insulating film is a silicon oxide film formed by thermal chemical vapor deposition using ozone and tetraethoxysilane as its materials.

7. The capacitor device of claim 1 further comprising
a second interlayer insulating film formed between the upper electrode and the stress control layer and causing tensile stress.

8. The capacitor device of claim 7, wherein
the second interlayer insulating film is a silicon oxide film formed by thermal chemical vapor deposition using ozone and tetraethoxysilane as its materials and subjected to heat treatment.

9. The capacitor device of claim 1 further comprising
a third interlayer insulating film formed over the semiconductor substrate and having an opening,
wherein the lower electrode is formed on the inner wall and bottom of the opening to form a concave shape in cross section.

10. The capacitor device of claim 1 further comprising
a fourth interlayer insulating film formed on the semiconductor substrate,
wherein the lower electrode is formed on the fourth interlayer insulating film to have a convex shape in cross section.

11. The capacitor device of claim 1 further comprising
a transistor formed on the semiconductor substrate and including a source and a drain,
wherein the lower electrode is electrically connected through a contact plug to the source or drain.

12. The capacitor device of claim 1, wherein
the capacitor insulating film is made of any one of SrBi₂(TaₓNb₁₋ₓ)₂O₉ (0≦x≦1), Pb(ZrₓTi₁₋ₓ)O₃ (0≦x≦1), (BiₓLa₁₋ₓ)₄Ti₃O₁₂ (0≦x≦1), and (BaₓSr₁₋ₓ)TiO₃ (0≦x≦1).
